(19) United States
(12) Patent Application Publication
(10) Pub. No.: US 2007/0249069 A1
(43) Pub. Date: Oct. 25, 2007

(54) Semiconductor devices and methods of manufacturing thereof

(76) Inventors: David Alvarez, Essex, VT (US); Kiran V. Chatty, Williston, VT (US); Cornelius Christian Russ, Diedorf (DE)

Correspondence Address: SLATER & MATSIL LLP, 17950 PRESTON ROAD, SUITE 1000, DALLAS, TX, 75252, US

(21) Appl. No.: 11/410,883

(22) Filed: Apr. 25, 2006

(51) Int. Cl. H01L 21/66

(52) U.S. Cl. 438/14

(57) ABSTRACT

A method of manufacturing a semiconductor device includes providing a workpiece comprising a plurality of active areas, and analyzing the active areas to determine desired stress levels for each active area. The method includes determining at least one first active area to have a first amount of stress and at least one second active area to have a second amount of stress. A stress-controlling material is formed over the at least one second active area, but not over the at least one first active area. A stress-increasing material is formed over the at least one first active area and over the stress-controlling material that is over the at least one second active area.

### TECHNICAL FIELD

The present invention relates generally to the fabrication of semiconductor devices, and more particularly to introducing stress to material layers of semiconductor devices.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon.

A transistor is an element that is utilized extensively in semiconductor devices. There may be millions of transistors on a single integrated circuit (IC), for example. A common type of transistor used in semiconductor device fabrication is a metal oxide semiconductor field effect transistor (MOSFET). A transistor typically includes a gate dielectric disposed over a channel region, and a gate formed over the gate dielectric. A source region and a drain region are formed on either side of the channel region within a substrate or workpiece.

In complementary metal oxide semiconductor (CMOS) devices, both positive and negative channel devices are used in complementary configurations. The positive and negative channel devices of CMOS devices are typically referred to as p channel metal oxide semiconductor (PMOS) and n channel metal oxide semiconductor (NMOS) transistors. A PMOS transistor is formed in an n well (e.g., a well implanted with n type dopants) and an NMOS transistor is formed in a p well. A shallow trench isolation (STI) region is typically formed between the n well and p well of the PMOS transistor and the NMOS transistor, respectively.

In some transistor designs, it is desirable to introduce stress to the channel region to improve the transistor performance.

What are needed in the art are improved methods and structures for introducing and controlling stress in channel regions of transistors and various other material layers of semiconductor devices.

### SUMMARY OF THE INVENTION

These and other problems are generally solved or circumvented, and technical advantages are generally achieved, by preferred embodiments of the present invention, which provide novel methods of introducing stress to, and controlling the stress of, channel regions of transistors and other material layers of semiconductor devices.

In accordance with a preferred embodiment of the present invention, a method of manufacturing a semiconductor device includes providing a workpiece comprising a plurality of active areas, and analyzing the active areas to determine desired stress levels for each active area. The method includes determining at least one first active area to have a first amount of stress and at least one second active area to have a second amount of stress. A stress-controlling material is formed over the at least one second active area, but not over the at least one first active area. A stress-increasing material is formed over the at least one first active area and over the stress-controlling material that is over the at least one second active area.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a cross-sectional view of a prior art semiconductor device, illustrating the effect on the stress of channel regions of transistors of a nitride layer disposed over the transistors;

FIGS. 2 through 4 show cross-sectional views of a prior art method of manufacturing a semiconductor device, wherein a masking material layer is used to block the formation of silicide on some regions of the semiconductor device;

FIGS. 5 through 9 show cross-sectional views of a preferred embodiment of the present invention at various stages of manufacturing, wherein a stress-controlling material is disposed over some regions of a semiconductor device, but not over other regions of the semiconductor device;

FIG. 10 is a cross-sectional view of another embodiment of the present invention, wherein the stress-controlling material may comprise an additional material layer of the semiconductor device;

FIG. 11 shows a cross-sectional view of a CMOS device, wherein the stress-controlling material is formed over one transistor of the CMOS device, but not over the other transistor of the CMOS device; and

FIGS. 12 and 13 are graphs illustrating some examples of the effect of the novel stress-controlling material on the performance of transistors in accordance with embodiments of the present invention.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely implemented in semiconductor devices comprising transistors. The invention may also be applied, however, to other semiconductor applications where controlling and adjusting the amount of stress of an underlying material layer is desired.

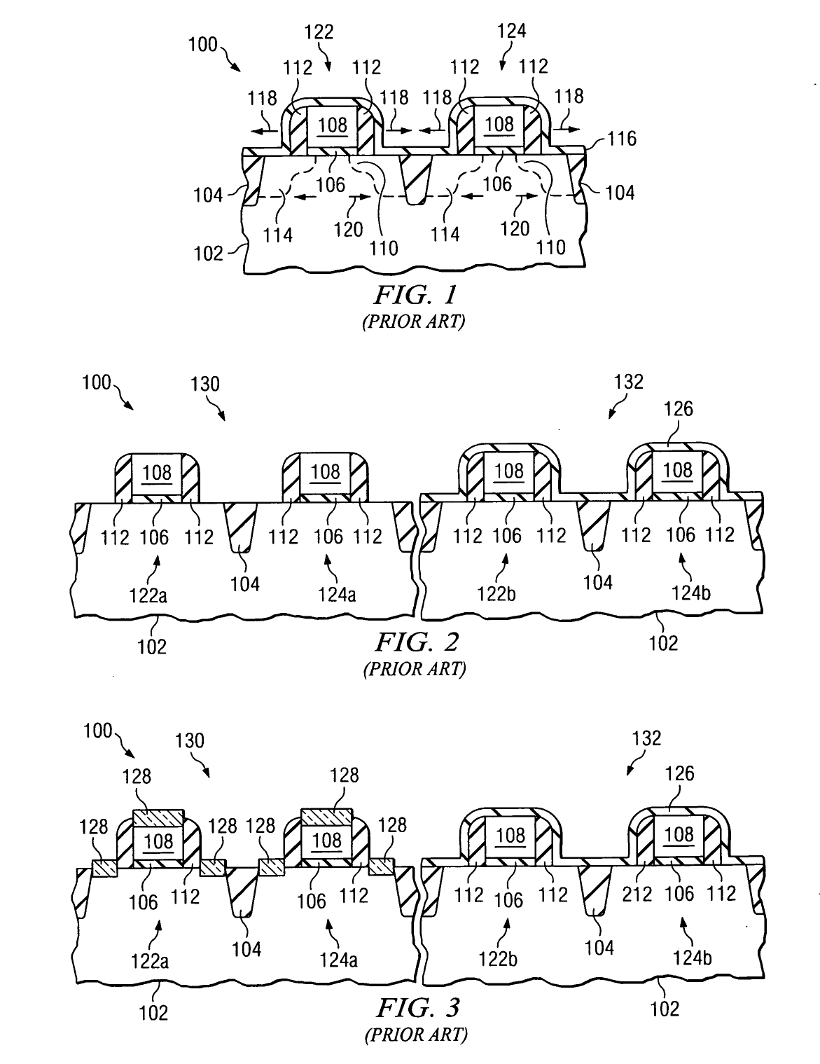

FIG. 1 shows a cross-sectional view of a prior art semiconductor device 100, illustrating the effect on the stress of channel regions of transistors 122 and 124 of a nitride material layer 116 disposed over the transistors 122 and 124. The semiconductor device 100 is typically fabricated by providing a workpiece 102 and forming STI regions 104 in the workpiece 102. A gate dielectric material 106 is deposited over the workpiece 102, and a gate material 108 is deposited over the gate dielectric material 106. The gate material 108 and the gate dielectric material 106 are patterned using lithography to form a gate 108 and gate dielectric 106. The workpiece 102 may be lightly doped with a dopant species to form lightly doped regions 110 in a top surface of the workpiece 102 proximate the gate 108 and gate dielectric 106 in source and drain regions of the transistors 122 and 124.

Spacers 112 comprising an insulating material are formed on the sidewalls of the gate 108 and gate dielectric 106. The workpiece 102 may include a deep implantation of a dopant species proximate the spacers 112 in the source and drain regions of the transistors 122 and 124, as shown at 114. Each transistor 122 and 124 includes a channel region disposed beneath the gate dielectric 106, between the source and drain regions 110/114.

In some semiconductor devices 100, a nitride material layer 116 may be formed over the gates 108, the sidewall spacers 112, and exposed portions of the source and drain regions 110/114, as shown. The nitride material layer 116 may comprise silicon nitride (SiₓN_{y}), which may comprise stress within the atomic and/or molecular structure, compared to the stress of the material layers 108, 112, and lightly doped regions 110 and deep implantation regions 114 of the source and drain regions that the nitride material layer 116 is formed on. The stress of the nitride material layer 116 is shown at 118, wherein the stress 118 comprises tensile stress, for example. The stress 118 of the nitride material layer 116 induces stress 120 within the workpiece 102, e.g., within the channel regions of the transistors 122 and 124, as shown.

Depending on the type of stress introduced, performance of transistors 122 and 124 may be improved or degraded. Mechanical stress changes the crystal lattice of the silicon, e.g., in the channel region, affecting the distance between the atoms of the channel region, which changes the mobility of holes or electrons in the channel region, for example.

Introducing stress to the channel region of a transistor 122 or 124 is advantageous in some applications, because the performance of the transistors 122 or 124 may be improved. For example, if mechanical stress is introduced to the channel region of a transistor 122 or 124, the mobility of the holes or electrons in the channel region is increased, which increases the on current, Iₒₙ, of the transistor.

However, in other applications, the performance of transistors 122 or 124 may be degraded by an increase in stress 120 in the channel region. For example, if the semiconductor device 100 comprises a CMOS device, the transistor 122 may comprise an NMOS field effect transistor (FET), and the transistor 124 may comprise a PMOS FET. Some NMOS FETs have demonstrated performance enhancement by the introduction of tensile stress to the channel region. However, some PMOS FETs may suffer from decreased performance if a tensile nitride material layer 116 is disposed over the transistor 124. Likewise, while some PMOS FETs have demonstrated performance enhancement by introduction of compressive stress to the channel region, NMOS FETs may suffer from decreased performance if a compressive stress material layer 116 is disposed over the transistor 124.

Thus, what are needed in the art are methods of forming and structures for semiconductor devices, wherein stress on underlying materials is introduced or increased in some regions, but wherein the stress introduced in other regions is reduced or controlled.

In some semiconductor devices 100, many different types of transistors 122 and 124 are formed across a workpiece 102 surface, with the different types of transistors 122 and 124 having different operating parameters and requirements. Some transistors 122 and 124 may comprise low voltage, high voltage, low standby power, or high performance devices, as examples.

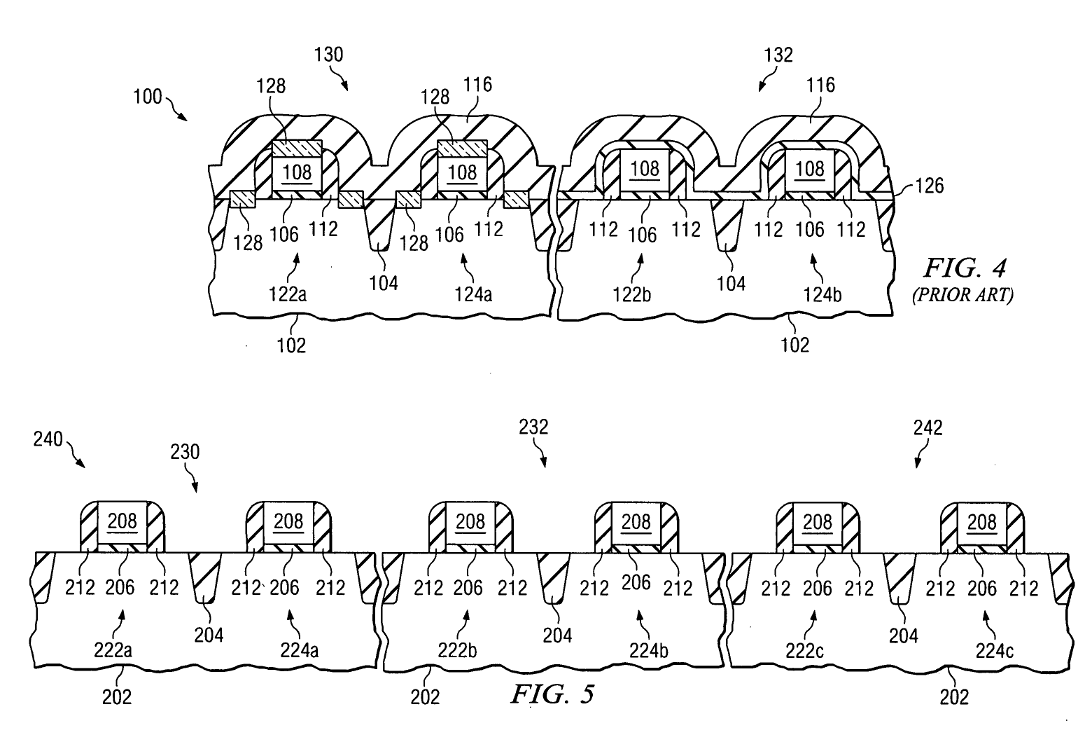

As an example, FIGS. 2 through 4 show cross-sectional views of a prior art method of manufacturing a semiconductor device 100 at various stages of manufacturing, wherein a masking material layer 126 is used to block the formation of silicide 128 in some regions 132 of the semiconductor device 100. Like numerals are used to describe the various elements in FIGS. 2 through 4 that were used to describe FIG. 1, and to avoid repetition, each reference number shown in FIG. 1 is not described again in detail herein.

Referring to FIG. 2, the workpiece 102 includes a first region 130 where transistors 122a and 124a are to be silicided, and a second region 132 where transistors 122b and 124b are not to be silicided; e.g., the second region 132 comprises a non-silicide region. The transistors 122a and 124a, and 122b and 124b, are formed in the first region 130 and the second region 132, respectively. Then the masking material layer 126, which may comprise an oxide or nitride material, as examples, is formed over the transistors 122b and 124b in the second region 132, as shown. The masking material layer 126 comprises a protective material that prevents the gates 108 and source and drain regions of the transistors 122a and 124b in the second region 132 from being silicided, as shown in FIG. 3.

To form the silicide 128 on the gates 108 and source and drain regions of the transistors 122a and 124a in the first region 130, a substance comprising a metal, such as Ti, Co, or Ni, as examples, is introduced into the chamber the semiconductor device 100 is being processed in, which causes the formation of the silicide 128 on the exposed semiconductive materials of the transistors 122a and 124a. The gates 108 and the source and drain regions of the transistors 122a and 124a of the exposed workpiece 102 typically comprise silicon or polysilicon, and thus, the gates 128 and source and drain regions are silicided during the silicidation process, as shown at 128, for example. The silicide 128 may comprise TiSiₓ, CoSiₓ, or NiSiₓ, as examples.

After the silicide 128 is formed, a layer of nitride material 116 is typically formed over the silicided transistors 122a and 124a in the first region 130 of the workpiece 102 and over the masking material layer 126 in the second region 130 of the workpiece 102, as shown in FIG. 4. The layer of nitride material 116 increases stress of the underlying material layer, e.g., of the workpiece 102. However, as described with reference to FIG. 1, it may be undesirable to increase stress of some devices 122a, 124a, 122b, or 124b formed in the workpiece 102, for example.

The masking material layer 126 is used in some semiconductor devices 100 to form a silicide 128 in some regions 130 but not in other regions 132, due to the performance requirements of transistors in the particular regions 130 and 132, for example. Some regions such as the first region 130 may require transistors 122a and 124a that have increased conductivity of the gates 108, source and drain regions, for example, whereas some regions such as the second region 132 may require transistors 122b and 124b that do not require increased conductivity of the gates 108, source and drain regions, and thus the masking material layer 126 is used to prevent silicide 128 formation in the second region 132.

U.S. Patent application publication no. 2005/0199958, entitled, “Method for Selectively Stressing MOSFETs to Improve Charge Carrier Mobility,” by Chen, et al., filed on Mar. 10, 2004, and U.S. Patent application publication no. 2006/0024879, entitled, “Selectively Strained MOSFETs to Improve Drive Current,” by Fu, et al., filed on Jul. 31, 2004, which patent application publications are hereby incorporated herein by reference, disclose forming a tensile stress layer over an NMOS device and forming a compressive stress layer over a PMOS device. However, these structures are problematic because a stress mismatch is created at the lateral interface of the tensile stress material layer and the compressive stress material layer. Furthermore, an additional lithography and etch step is required for each of the tensile stress material layer and the compressive stress material layer, which is costly and time-consuming.

Embodiments of the present invention provide novel structures and methods of controlling and modulating the amount of stress introduced to underlying material layers by a subsequently deposited stress-increasing material, by the use of a stress-controlling material in some regions of the workpiece. In some embodiments, a material layer already in use for another purpose in the semiconductor device may be used as the stress-controlling material, such as the masking material layer 126 shown in FIGS. 2 through 4 that is used to prevent silicide formation in some regions. In other embodiments, the stress-controlling material may alternatively comprise an additional material layer in the fabrication of a semiconductor device, for example, to be described further herein.

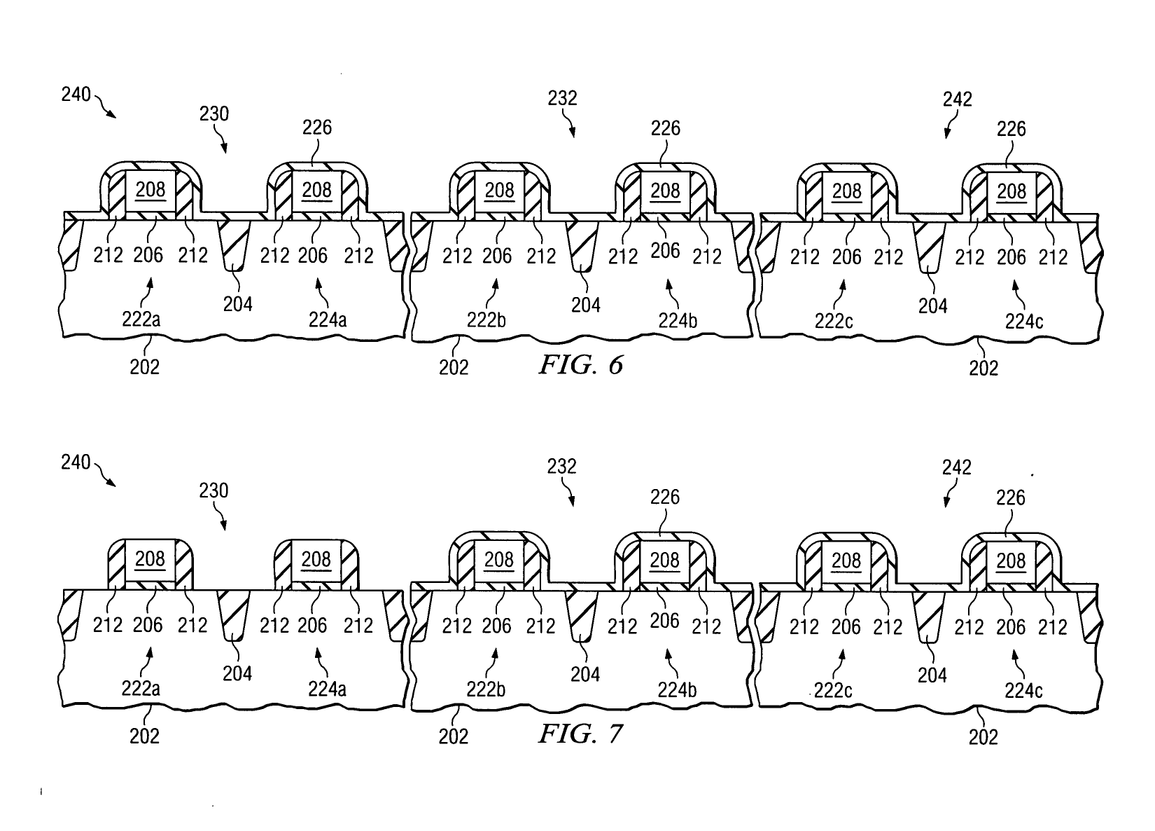

FIGS. 5 through 9 show cross-sectional views of a preferred embodiment of the present invention at various stages of manufacturing, wherein the novel stress-controlling material is disposed over some regions of a semiconductor device, but not over other regions of the semiconductor device. In this embodiment, a masking material layer that is used for other purposes of a semiconductor device design is modified so that the masking material layer is also used as a stress-controlling material. For example, the masking material layer may be formed over regions that were previously not covered by the masking material layer, so that the masking material layer provides stress control and screening in those regions, to be described further herein. Like numerals are used to describe the various elements in FIGS. 5 through 9 that were used to describe FIGS. 1 and 2 through 4.

Referring next to FIG. 5, to manufacture the novel semiconductor device 240, first, a workpiece 202 is provided. The workpiece 202 may include a semiconductor substrate comprising silicon or other semiconductor materials, for example. The workpiece 202 may also include other active components or circuits, not shown. The workpiece 202 may comprise silicon oxide over single-crystal silicon, for example. The workpiece 202 may include other conductive layers or other semiconductor elements, e.g., transistors, diodes, etc. Compound semiconductors, GaAs, InP, or SiC, as examples, may be used in place of silicon, as examples. The workpiece 202 may comprise a silicon-on-insulator (SOI) substrate, for example.

The workpiece 202 preferably comprises a first region 230, a second region 232, and a third region 242, as shown. The first region 230 is also referred to herein as a silicide region. The first region 230 preferably comprises one or more active areas that will be silicided in a later manufacturing process step. The second region 232 is also referred to herein as a non-silicide region. The second region 232 preferably comprises one or more active areas that will not be silicided in the silicide process to form silicided areas in the silicide region 230. The third region 242 is also referred to herein as a stress-control region. The third region 242 preferably comprises one or more active areas in which the stress that may be induced or increased by a subsequently deposited stress-increasing material is controlled or reduced, in accordance with a preferred embodiment of the present invention.

STI regions 204 may be formed in the workpiece 202, by patterning the workpiece 202 using lithography, e.g., by depositing a layer of photoresist over the workpiece 202, patterning the layer of photoresist (not shown) using a lithography mask, removing portions of the layer of photoresist, using the layer of photoresist as a mask while exposed portions of the workpiece 202 are etched away using an etch process, and then removing or stripping away the layer of photoresist. The patterned portions of the workpiece 202 are filled with an insulating material such as silicon dioxide to form the STI regions 204. The STI regions 204 are preferably formed before the formation of the transistors 222a, 224a, 222b, 224b, 222c, and 224c in some embodiments, although alternatively, the STI regions 204 may be formed after the transistors 222a, 224a, 222b, 224b, 222c, and 224c are formed. In some applications, STI regions 204 may not be required, for example, not shown.

A gate dielectric material 206 comprising an insulator such as silicon dioxide, silicon nitride, a high dielectric constant (k) material, or other insulating material is deposited over the workpiece 202, and a gate material 208 is deposited over the gate dielectric material 206. The gate dielectric material 206 may comprise a thickness of about 250 Angstroms or less, as an example, although alternatively, the gate dielectric material 206 may comprise other dimensions. The gate material 208 preferably comprises a semiconductor material such as silicon or polysilicon, as examples, although other semiconductor materials and conductors may also be used. The gate material 208 may comprise a thickness of about 2,000 Angstroms or less, as an example, although alternatively, the gate material 208 may comprise other dimensions. The gate material 208 and the gate dielectric material 206 are patterned using lithography to form a gate 208 and gate dielectric 206 of the transistors 222a, 224a, 222b, 224b, 222c, and 224c.

Optionally, exposed portions of the workpiece 202 may be lightly doped with a dopant species to form lightly doped regions (not shown) proximate the gate 208 and gate dielectric 206 within an upper portion of the workpiece 202. Spacers 212 comprising an insulating material are formed on the sidewalls of the gate 208 and gate dielectric 206. The spacers 212 may comprise one or more layers of silicon oxide, silicon nitride, or SiON, as examples, although alternatively, other materials may also be used. For example, the spacers 212 may comprise a liner comprising silicon nitride or silicon oxide that is substantially conformal and covers all exposed surfaces. The spacers 212 may include an insulating material formed over the liner that comprises silicon oxide or silicon nitride, wherein the insulating material comprises a different material than the liner, for example. The insulating material and liner of the spacers 212 may be patterned and/or etched, e.g., using an anisotropic etch process to form downwardly sloping sidewalls on the insulating material of the spacers 212, as shown, although alternatively, other etch processes may also be used to form the spacers 212.

After the formation of the sidewall spacers 212, optionally, the workpiece 202 may be implanted with a deep implantation of a dopant species (not shown) to form a source region and a drain region proximate the spacers 212.

In the embodiment shown, the first region 230 comprises two or more transistors 222a and 224a, the second region 232 comprises two or more transistors 222b and 224b, and the third region 242 comprises two or more transistors 222c and 224c, respectively, formed therein, as shown. Alternatively, the first region 230, second region 232, and third region 242 may include other types of active areas or devices formed therein, for example. The first region 230, second region 232, and third region 242 may alternatively comprise one or more memory devices, switches, conductive lines, diodes, capacitors, logic circuits, other electronic components, combinations thereof, or combinations thereof with one or more transistors, as examples. In the embodiment shown, the regions of the workpiece 202 proximate the spacers 212 comprise the source and drain regions of the transistors 222a, 224a, 222b, 224b, 222c, and 224c, for example.

A first material 226 is formed over the first region 230, second region 232, and third region 242 of the workpiece 202, as shown in FIG. 6. The first material 226 is also referred to herein as a stress-controlling material, for example. The first material 226 preferably comprises a nitride material comprising at least silicon and nitrogen such as silicon nitride, although other insulating materials and stress-controlling materials may also be used for the first material 226, for example. The first material 226 may comprise a nitride material such as silicon and nitrogen, combined with another element, such as oxygen (SiON), for example. The first material 226 may alternatively comprise an oxide such as silicon dioxide, in some embodiments, for example. The first material 226 preferably comprises a thickness of about 40 nm or less, and more preferably comprises a thickness of about 25 nm in some embodiments, as examples, although the first material 226 may also comprise other dimensions. The first material 226 preferably comprises a material adapted to screen or control the amount of stress that a subsequently deposited stress-increasing material has on an underlying material layer, such as channel regions of the transistors 222a, 224a, 222b, 224b, 222c, and 224c.

The first material 226 is patterned using lithography to remove the first material 226 from the first region 230 of the workpiece 202 and leave the first material 226 remaining on the second region 232 and the third region 242, as shown in FIG. 7. For example, a layer of photosensitive material (not shown) may be deposited over the first material, and the layer of photosensitive material is patterned with the desired pattern using a lithography mask. The layer of photosensitive material is developed, and the layer of photosensitive material is used as a mask while portions of the first material 226 are etched away. The layer of photosensitive material is then removed.

In some embodiments, the first material 226 preferably comprises a masking material layer (e.g., such as the masking material layer 126 shown in FIGS. 3 and 4) that was previously used, e.g., in earlier design stages of the semiconductor device 240 for other purposes, such as for silicidation protection. The lithography mask for patterning the masking material layer is altered so that the first material 226 is formed over some regions, e.g., such as the third region 242, wherein the masking material layer was not formed in the earlier design stage. In particular, the lithography mask (not shown) used to pattern the masking material layer of a semiconductor device design is preferably modified so that the masking material layer (the first material 226) is also used as a stress-controlling material in the third region 242. For example, the first material 226 is formed over regions that were previously not covered by the masking material layer, so that the first material 226 or masking material layer provides stress control in those regions, e.g., in the third region 242, as shown in FIG. 7.

The semiconductor device 240 is exposed to a silicidation process to form a silicide 228 on exposed semiconductive materials, such as the gates 208 and the source and drain regions proximate the top surface of the workpiece 202 of the transistors 222a and 224a in the first region 230, as shown in FIG. 8.

A second material 216 is deposited over and abutting the transistors 222a and 224a in the first region 230 and over the first material 226 in the second region 232 and the third region 242, as shown in FIG. 9. The second material 216 is also referred to herein as a stress-increasing material, for example. The second material 216 is adapted to increase the stress of an underlying material layer, e.g., such as the stress of a channel region disposed between source and drain regions of transistors 222a, 224a, 222b, 224b, 222c, and 224c, for example. The second material 216 preferably comprises a nitride material such as silicon nitride, although other insulating materials and stress-controlling materials may also be used for the second material 216, for example, such as SiON. The second material 216 preferably comprises a thickness of about 75 nm or less, and more preferably comprises a thickness of about 50 nm in some embodiments, as examples, although the second material 216 may also comprise other dimensions. The second material 216 preferably comprises a greater mechanical stress than the first material 226, in some embodiments, for example.

After the formation of the transistors 222a, 224a, 222b, 224b, 222c, and 224c, the channel regions of the transistors 222a, 224a, 222b, 224b, 222c, and 224c comprise a first amount of stress, in some embodiments. The first amount of stress may be due to the physical properties of the workpiece 202 and materials of the gate dielectric 206, gate 208, spacers 212, and STI regions 204 proximate the channel regions, for example. The stress-increasing material 216 disposed over the transistors 222a and 224a in the first region 230 increases the first amount of stress in the first region 230 of the workpiece by a second amount of stress. For example, the stress 218 of the stress-increasing material 216 increases the stress 220 of the channel region of the transistors 222a and 224a in the first region 230, as shown.

However, due to the presence of the first material or stress-controlling material 226 in the second region 232 and the third region 242, the stress-increasing material 216 has less of an impact of the stress 248 in the channel regions of the transistors 222b, 224b, 222c, and 224c in the second region 232 and the third region 242. For example, the stress-increasing material 216 increases the first amount of stress in the second region 232 and the third region 242 of the workpiece 202 by a third amount of stress 246, the third amount of stress being different than the second amount of stress 218. The third amount of stress 246 is preferably less than the second amount of stress 218 in some embodiments, for example. The stress-controlling material 226 reduces the amount that the stress-increasing material 216 increases the first amount of stress by about the second amount of stress 218 less the third amount of stress 246, for example. The second amount of stress 218 and the third amount of stress 246 may comprise tensile or compressive stress, for example. Preferably, the resulting stress 248 in the channel regions of the transistors 222b, 224b, 222c, and 224c in the second region 232 and the third region 242 is less than the resulting stress 220 in the channel regions of the transistors 222a and 224a in the first region 230, for example.

Because the first material 226 is closer to and directly abuts the transistors 222b, 224b, 222c, and 224c, the stress of the first material 226 has more of an impact on the stress 248 of the channel regions of the transistors 222b, 224b, 222c, and 224c than the second material 216. Thus, the first material 226 controls, screens, or limits the effect of the stress of the second material 216 on the channel regions of the transistors 222b, 224b, 222c, and 224c, for example. However, the stress of the second material 216, which is greater than the stress of the first material 226 in some embodiments, is closer to and directly abuts the transistors 222a and 224a, and thus, the stress 220 of the channel regions of transistors 222a and 224a is increased by a greater amount than the stress 248 of the channel regions of transistors 222b, 224b, 222c, and 224c is increased.

Additional insulating material layers 244 and conductive materials (not shown) may be formed over the semiconductor device 240 to complete the semiconductor device 240 manufacturing process. The insulating material layers 244 and conductive materials may then be patterned to make electrical contact to portions of the transistors 222a, 224a, 222b, 224b, 222c, and 224c, for example, not shown.

The first material or stress-controlling material 226 preferably comprises the same material as the second material or stress-increasing material 216 in some embodiments, for example. The first material or stress-controlling material 226 preferably is deposited using different parameters, such as deposition pressure, deposition rate, gas ratios, radio frequency (RF) power and frequency, and other parameters, than the parameters used to deposit the second material 216, for example. The first material 226 may comprise a different thickness than the second material 216, in some embodiments, for example. The deposition process of the first material 226 and/or second material 216 may comprise a plasma deposition or other deposition method, for example.

Preferably the material and deposition process for the first material 226 is selected or tuned to achieve the amount of control desired on the stress of the underlying material layer, e.g., such as the channel regions of the transistors 222b, 224b, 222c, and 224c in the second region 232 and the third region 242, of the effect of the second material 216. For example, a stress-control amount for the first amount of stress in the second and third regions 232 and 242 of the workpiece 202 may be determined, and then a deposition process for the first material 226 is selected to achieve the amount of control on the stress of the underlying material layers is determined.

Table 1 illustrates some examples of the amount of stress of the material layers described herein and also the stress in the underlying material layer, e.g., the channel region of the transistors.

TABLE 1

| Material layer implemented | Stress | Type of Stress |
|---|---|---|
| Stress-controlling material 226 | −105 MPa | Compressive |
| only | | |
| Stress-increasing material 216 | +714 MPa | Tensile |
| only | | |
| Both stress-controlling | +447 MPa | Tensile |
| material 226 and stress- | | |
| increasing material 216 | | |

For example, depositing a stress-controlling material 226 only in the second region 232 or third region 242 may cause a compressive stress in an underlying channel of a transistor of about −105 MPa, and depositing a stress-increasing material 216 only in the first region 230 may cause a tensile stress in an underlying channel of a transistor of about +714 MPa. Using both the stress-controlling material 226 and the stress-increasing material 216 in the second region 232 and third region 242 results in an induced stress in the channel regions of the underlying transistors of about +447 MPa, for example.

Some examples of methods of forming the stress-controlling material 226 will next be described. Preferably, in some embodiments, the stress of the stress-controlling material or first material 226 is tuned by process conditions during plasma deposition, such as pressure, deposition rate, deposition time, gas ratios, gas flow rate, RF power and frequency, and other parameters, as examples. For example, forming the stress-controlling material 226 preferably comprises forming a material layer having a predetermined amount of stress control on the stress-increasing material 216 on the channel region of the underlying transistor, wherein the predetermined amount of stress control is achieved by selecting deposition parameter values of pressure, deposition rate, deposition time, gas ratio, gas flow rate and/or RF power and/or frequency. Because the stress-controlling material 226 is disposed closest and adjacent or abutting the workpiece 202, the stress-controlling material 226 affects the stress of the channel region of the transistors in the second region 232 and third region 242.

In a first example of an embodiment of the present invention, the stress-controlling material 226 comprises a layer of silicon nitride formed at a first heater temperature, a first pressure, a first high frequency RF power, a first low frequency RF power, a first SiH₄ flow rate, a first NH₃ flow rate, a first N₂ flow rate, a first deposition rate, and a first deposition time. The thickness of the stress-controlling material 226 in this example was about 25 nm. The resulting stress of the stress-controlling material 226 comprising silicon nitride formed using these parameters was found to be about 300 MPa (compressive stress).

In a second example of an embodiment of the present invention, the stress-controlling material 226 comprises a layer of silicon nitride formed using the following parameters: the first heater temperature (e.g., the same temperature used in the first example), a second pressure, the second pressure being greater than the first pressure of the first example, the first high frequency RF power of the first example, a second low frequency RF power, the second low frequency RF power being less than the first low frequency RF power of the first example, a second SiH₄ flow rate, the second SiH₄ flow rate being less than the first SiH₄ flow rate of the first example, the first NH₃ flow rate, a second N₂ flow rate, the second N₂ flow rate being greater than the first N₂ flow rate, a second deposition rate, the second deposition rate being less than the first deposition rate of the first example, and a second deposition time, the second deposition time being greater than the first deposition time of the first example. The thickness of the stress-controlling material 226 in this example was about 25 nm. The resulting stress of the stress-controlling material 226 comprising silicon nitride formed using these parameters was found to be about 1.2 GPA (tensile stress).

In a third example of an embodiment of the present invention, the stress-controlling material 226 comprises a layer of silicon nitride formed using the following parameters: the first heater temperature (e.g., the same temperature used in the first example), a third pressure, the third pressure being greater than the second pressure of the second example, a second high frequency RF power, the second high frequency RF power being less than the first high frequency RF power of the first and second examples, the second low frequency RF power of the second example, a third SiH₄ flow rate, the third SiH₄ flow rate being less than the second SiH₄ flow rate of the second example, a second NH₃ flow rate, the second NH₃ being less than the first NH₃ flow rate of the first and second examples, a third N₂ flow rate, the third N₂ flow rate being greater than the second N₂ flow rate of the second example, a third deposition rate, the third deposition rate being less than the second deposition rate of the second example, and a third deposition time, the third deposition time being greater than the second deposition time of the second example. The thickness of the stress-controlling material 226 in this example was about 25 nm. The resulting stress of the stress-controlling material 226 comprising silicon nitride formed using these parameters was found to be about 1.3 GPa (tensile stress).

The effects of the stress-controlling material 226 and the stress-increasing material 216 on the underlying material layer may be measured using a variety of methods. For example, the stress of the film itself (e.g., the stress-controlling material 226 and the stress-increasing material 216) can be measured by wafer or workpiece 202 bow measurements, e.g., by the optical measurement of bowing before and after the deposition. The effects of the stress-controlling material 226 and the stress-increasing material 216 on the channel region of a transistor may also be determined by electrical tests of the transistors 222a, 224a, 222b, 224b, 222c, and 224c, for example.

Devices other than transistors may be formed in the regions 230, 232 and 242 shown in FIGS. 5 through 9. The device in regions 230, 232 and 242 may comprise active areas comprising transistors and/or other electronic components and elements, for example.

In accordance with another embodiment of the present invention, a method of manufacturing a semiconductor device 240 includes providing a workpiece 202 comprising a plurality of active areas, and analyzing the active areas to determine desired stress levels for each active area. The method includes determining at least one first active area to have a first amount of stress and at least one second active area to have a second amount of stress. A stress-controlling material 226 is formed over the at least one second active area, but not over the at least one first active area. A stress-increasing material 216 is formed over the at least one first active area and over the stress-controlling material 226 that is over the at least one second active area. In this embodiment, the second amount of stress is preferably less than the first amount of stress, and the stress-controlling material 226 reduces the amount that the stress-increasing material 216 increases a stress level of the at least one second active area. The at least one first active area may be disposed in a first region (e.g., such as region 230), and the at least one second active area may be disposed in a second region (e.g., such as region 242). In another embodiment, a material layer (not shown) may be disposed over the workpiece 202, the material layer comprising a third amount of stress, wherein the stress-increasing material increases the third amount of stress of the material layer in the first region by a greater amount than in the second region.

Embodiments of the present invention may be implemented in structures other than in the transistor 222a, 224a, 222b, 224b, 222c, and 224c structures shown in the drawings. For example, in some embodiments, a material layer (not shown) may be deposited or formed over the workpiece 202, wherein the material layer comprises a first amount of stress. In this embodiment, the second material or stress-increasing material 216 increases the first amount of stress of the material layer in the first region by the second amount of stress previously described herein and increases the first amount of stress of the material layer in the second region by the third amount of stress, for example.

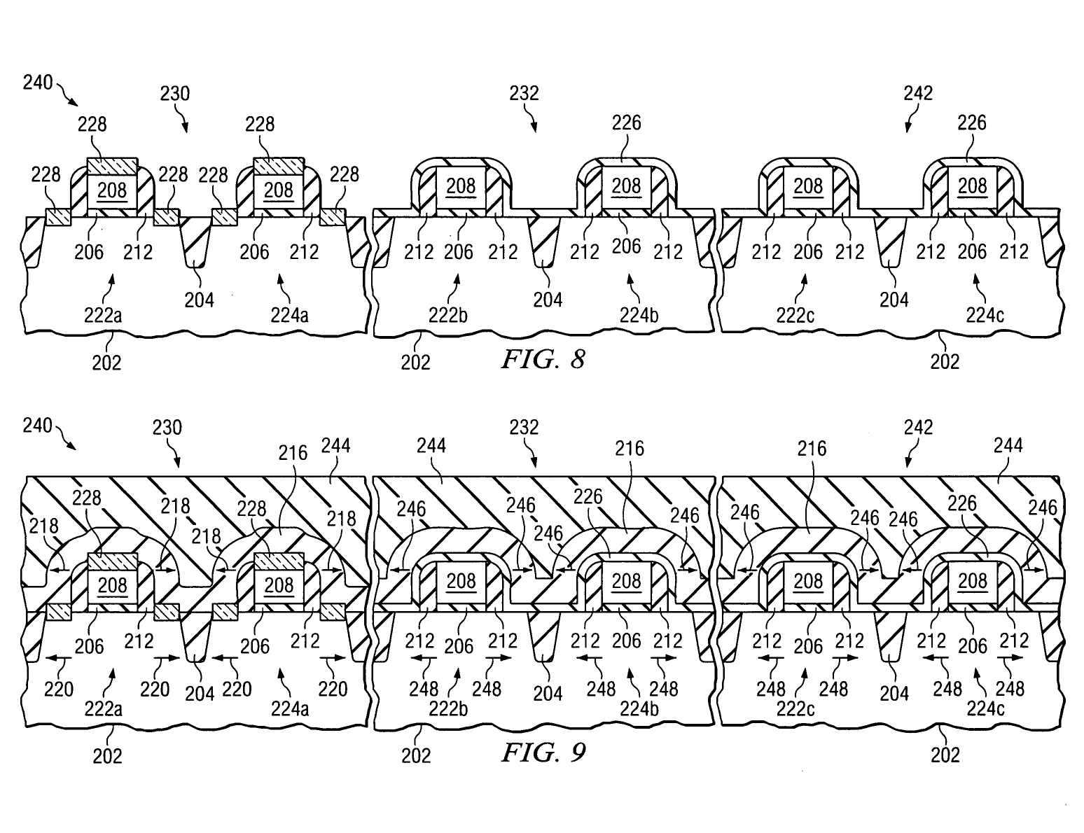

FIG. 10 is a cross-sectional view of another embodiment of the present invention, wherein the novel stress-controlling layer described herein may comprise an additional, third material layer 350 of the semiconductor device 340, as shown in phantom in FIG. 10. Again, like numerals are used for the various elements that were described in FIGS. 1, 2 through 4, and 5 through 9. To avoid repetition, each reference number shown in FIG. 10 is not described again in detail herein. Rather, similar materials x02, x04, x06, x08, etc . . . are preferably used for the various material layers shown as were described for FIGS. 1, 2 through 4, and 5 through 9, where x=1 in FIGS. 1, and 2 through 4, x=2 in FIGS. 5 through 9, and x=3 in FIG. 10. As an example, the preferred and alternative materials and dimensions described for the first material 226 and second material 216 in FIGS. 5 through 9 are preferably also used for the first material 326 and second material 316 shown in FIG. 10.

The third material 350 preferably comprises similar materials, dimensions, and deposition methods and parameters as described for the first material 226 or stress-controlling material 226 shown in FIGS. 5 through 9, for example. The first material 326 may not be included in the third region 342 in this embodiment (not shown in FIG. 10), for example. Rather, the first material 326 may be formed in only the second region 332 of the workpiece 302. Alternatively, the first material 326 may be formed in only the third region 342 of the workpiece 302, also not shown. The third material 350 may be formed over the active areas of at least the second or non-silicide region 342 either before or after disposing the first material 326 over the active areas in at least the first region or stress-control region 330, in some embodiments, for example. The third material 350 may also be formed over the first region 330 after the formation of the silicide 328, as shown in phantom.

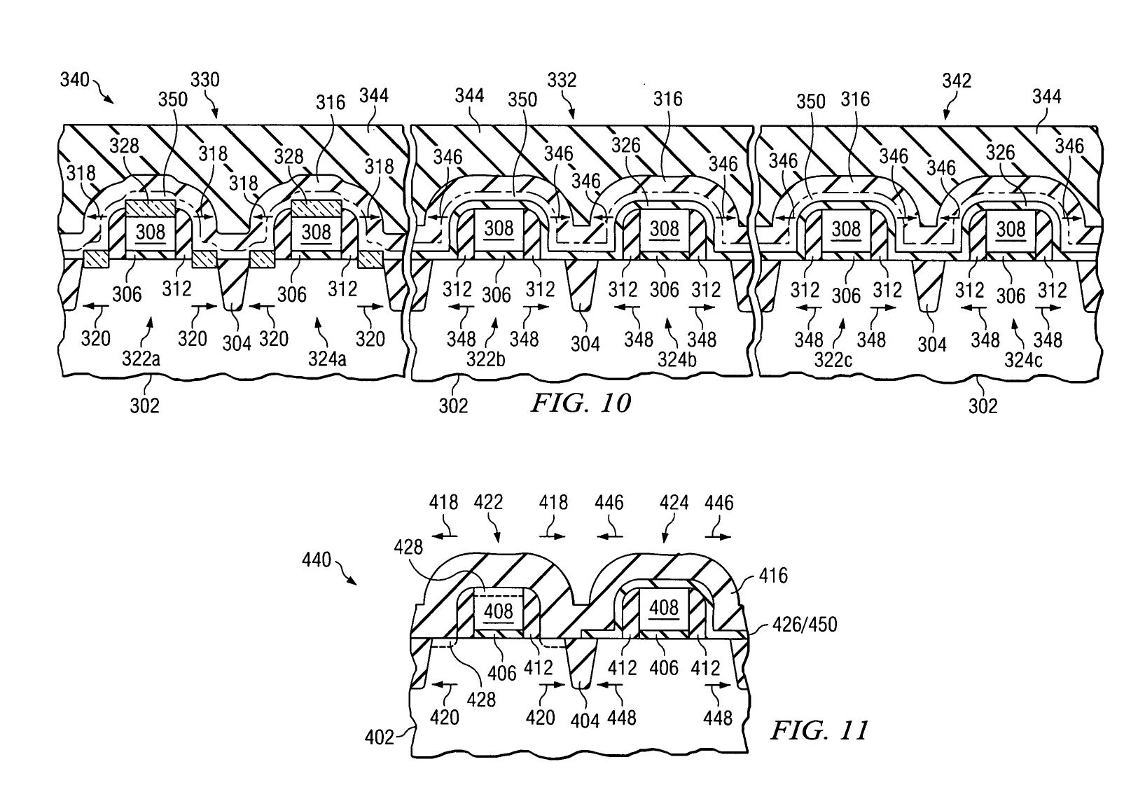

FIG. 11 shows a cross-sectional view of a semiconductor device 440, wherein the stress-controlling layer 426/450 is formed over one transistor 424 of a CMOS device, but not over the other transistor 422 of the CMOS device. Again, like numerals are used for the various elements that were used to describe the previous figures, and to avoid repetition, each reference number shown in FIG. 11 is not described again in detail herein. In this embodiment, if the stress-increasing material 416 comprises tensile stress, the first transistor 422 preferably comprises an NMOS FET, and the second transistor 424 preferably comprises a PMOS FET. The stress-controlling material/first material/third material 426 or 450 is preferably formed over the PMOS FET 424 but not over the NMOS FET 422 to screen the stress effect of the stress-increasing material 416 on the PMOS FET 424, as shown. Alternatively, for example, if the stress-increasing material 416 comprises compressive stress, the first transistor 422 preferably comprises a PMOS FET, and the second transistor 424 preferably comprises an NMOS FET. The stress-controlling material/first material/third material 426 or 450 is preferably formed over the NMOS FET 424 but not over the PMOS FET 422 to screen the stress effect of the stress-increasing material 416 on the NMOS FET 424, for example.

In the embodiment wherein the stress-increasing material 416 comprises tensile stress and the first transistor 422 comprises an NMOS FET, advantageously, the stress-increasing material 416 is formed directly over and abutting portions of the workpiece 402 in the source region and drain region of the NMOS FET 422, increasing the operating current and improving the performance of the NMOS FET 422 by increasing the stress of the channel region, and the stress-controlling material 426 or 450 limits or screens the effect of the stress-increasing material 416 on the channel region of the PMOS FET 424 so that the performance of the PMOS FET 424 is not compromised or decreased, for example. The novel stress-controlling material 426 or 450 disposed between the PMOS FET 424 and the stress-increasing material 416 results in less performance degradation of the PMOS FET 424, for example.

Likewise, if the stress-increasing material 416 comprises compressive stress, the stress-controlling material 426 or 450 may be formed over an NMOS FET but not a PMOS FET, resulting in the formation of a PMOS FET with increased operating current and improved performance due to the stress-increasing material 416 formed directly over and abutting portions of the workpiece 402 in the source and drain regions of the PMOS FET, yet wherein the NMOS FET has less performance degradation, due to the presence of the stress-controlling material 426 or 450 between the NMOS FET and the stress-increasing material 416, for example.

In the embodiment shown in FIG. 11, the stress-controlling material 426 or 450 may comprise a first material 426 that is a material layer that is also used for another purpose in the fabrication of the semiconductor device 440, such as blocking silicide formation in non-silicide regions (not shown in FIG. 11; see FIG. 8 at second region 232). Alternatively, the stress-controlling material 426 or 450 may comprise a third material 450 that is an additional material layer used specifically for controlling the stress of the underlying material layers, e.g., by screening or limiting the effect of the stress-increasing or second material 416.

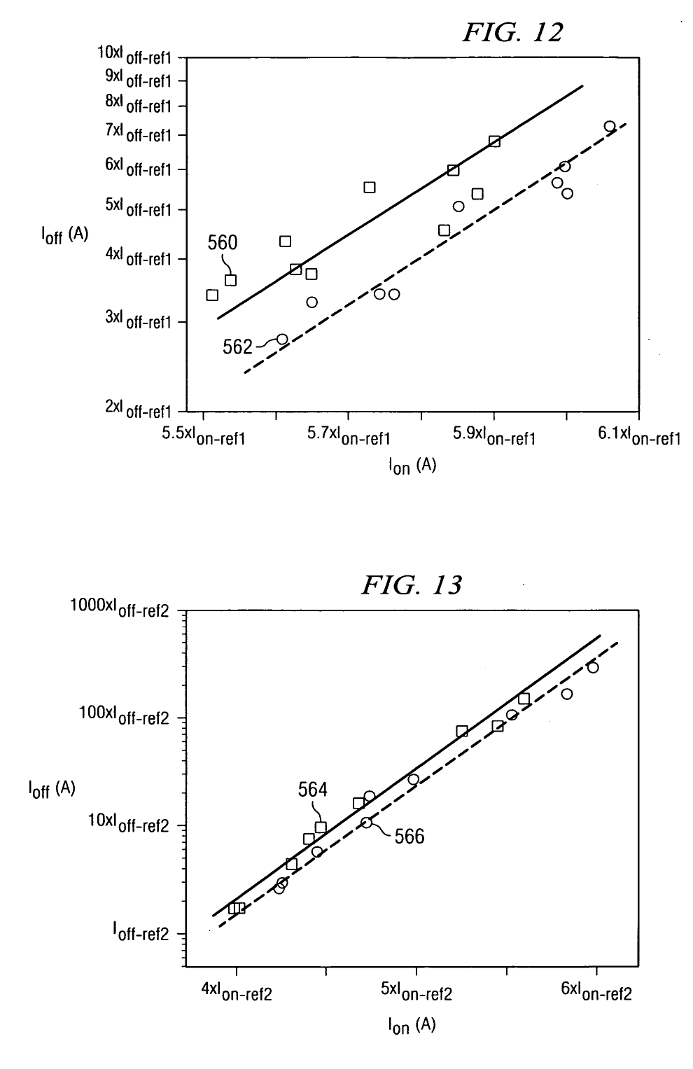

FIGS. 12 and 13 are graphs illustrating some examples of the effect of the novel stress-controlling materials 226, 326, 350, 426, and 450 on the performance of transistors in accordance with embodiments of the present invention, wherein the stress-increasing material 216, 316, 416 comprises tensile stress. Graphs of the “off” current I_{off} vs. the “on” current Iₒₙ (e.g., the operating current) of transistors are shown in FIGS. 12 for reference values of current I_{on-ref1} and I_{off-ref1}. Graphs of I_{off} vs. Iₒₙ are shown in FIG. 13 for reference values of current I_{on-ref2} and I_{off-ref2}.

In FIG. 12, measurements were made for 2.5 volt (V) PMOS FET devices having a gate length and width of about 0.24×20 μm of the off current I_{off} vs. the on current Iₒₙ. Results for devices not having the stress-controlling material 226, 326, 350, 426, and 450 disposed over the PMOS FETs are shown at 560, and results for devices including the stress-controlling material 226, 326, 350, 426, and 450 disposed over the PMOS FETs are shown at 562. An improvement in performance of an average of about 2.25% was observed in PMOS FETs having the novel stress-controlling material 226, 326, 350, 426, and 450 of embodiments of the present invention implemented in the structure. For example, the Iₒₙ increased or improved by about 2.2 to 2.3%, or an average of about 2.25%, for each I_{off}, as shown. Similar improvements in NMOS FETs may be achieved if the stress of the stress-increasing material 216, 316, or 416 comprises compressive stress, for example, by disposing the novel stress-controlling materials 226, 326, 350, 426, and 450 between the NMOS FETs and the stress-increasing material 216, 316, or 416 described herein.

In FIG. 13, measurements were made for 1.0 V PMOS FET devices having a gate length and width of about 0.06×20 μm of the off current I_{off} vs. the on current Iₒₙ. Results for devices not having the stress-controlling material disposed over the PMOS FETs are shown at 564, and results for devices including the stress-controlling material disposed over the PMOS FETs are shown at 566. An improvement in performance of an average of about 2.55% was observed in PMOS FETs having the novel stress-controlling material 226, 326, 350, 426, and 450 of embodiments of the present invention implemented in the structure. For example, the Iₒₙ increased by about 2.2 to 2.9%, or an average of about 2.55%, for each I_{off}, as shown.

The graphs shown in FIGS. 12 and 13 illustrate that for smaller gate lengths, even more improved performance of transistors may be achieved by implementing the novel stress-controlling material 226, 326, 350, 426, and 450 of embodiments of the present invention.

Thus, embodiments of the present invention comprise novel methods and structures wherein one material layer 226, 326, 350, 426, and 450 is disposed under another material layer 216, 316, or 416 to selectively control the stress of some devices on a semiconductor workpiece. Some of the devices on the semiconductor workpiece may be silicided, or none of the devices may be silicided, for example.

The stress-control material may be an additional material layer that requires an additional lithography step and an additional etch step, in some embodiments. However, a lateral interface between a tensile stress layer and a compressive stress layer is avoided, because the stress-controlling material 226, 326, 350, 426, and 450 is formed on some regions of the workpiece but not others. Furthermore, the embodiments of the present invention described herein require fewer lithography and etch steps, resulting in a cost savings.

In some embodiments, a nitride layer used for another purpose such as silicide formation protection in some regions is used for the stress-controlling layer, which saves one extra mask in the process, which is advantageous in many types of circuits.

Embodiments of the present invention include providing novel semiconductor devices 240, 340, and 440 and transistors 222a, 224a, 222b, 224b, 222c, 224c, 322a, 324a, 322b, 324b, 322c, 324c, 422 and 424 including the first material 226, 326, and 426, second material 215, 315, and 416, and optional third material 350 and 450 described herein. Embodiments of the present invention also include methods of fabricating the semiconductor devices 240, 340, and 440 and transistors 222a, 224a, 222b, 224b, 222c, 224c, 322a, 324a, 322b, 324b, 322c, 324c, 422 and 424, for example.

Advantages of embodiments of the invention include providing novel structures and methods for increasing the stress of underlying material layers of some regions of a workpiece, yet controlling or decreasing the amount of stress introduced to underlying material layers in other regions of a workpiece. The stress-controlling material 226, 326, 350, 426, and 450 is preferably used in some regions of a semiconductor device, but not in other regions.

In some embodiments, a material layer currently being used in a semiconductor device design to block silicide formation in some regions of a workpiece may be modified or patterned to also be used as the novel stress-controlling material 226, 326, 350, 426, and 450 described herein. This is advantageous because an additional material layer is not required; rather, a change to the lithography mask for the silicide-blocking material layer may be implemented to form the stress-controlling material in some regions of the workpiece, which results in a cost savings.

In other embodiments, an additional material layer may be used as the stress-controlling material 226, 326, 350, 426, and 450, for example.

Two or more layers of the stress-controlling material 226, 326, 350, 426, and 450 may be used in a semiconductor device design (not shown in the drawings), disposed beneath the stress-increasing material 216, 316, and 416, to allow the tuning of stress in two or more regions across the surface of a semiconductor device, in accordance with embodiments of the present invention. For example, one stress-controlling material 236, 326, 350, 426, or 450 may be formed in one region using a first set of processing parameters, and another stress-controlling material 236, 326, 350, 426, or 450 may be formed in another region using a second set of processing parameters. The first and second set of processing parameters may be different so that the stress-control amount for each region is different, for example.

The stress-controlling material 236, 326, 350, 426, or 450 may comprise a first stress-controlling material disposed beneath the stress-increasing material 216, 316, and 416 over the active areas in a first portion of the stress-control region and a second stress-controlling material disposed beneath the stress-increasing material 216, 316, and 416 over the active areas in a second portion of the stress-control region, for example. The first stress-controlling material may reduce an effect of the stress-increasing material 216, 316, and 416 on the active areas by a first amount, and the second stress-controlling material may reduce an effect of the stress-increasing material 216, 316, and 416 on the active areas by a second amount, wherein the second amount is different than the first amount, for example.

CMOS devices with improved performance may be achieved by some embodiments of the present invention, as shown in FIGS. 11, 12, and 13.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of manufacturing a semiconductor device, comprising:
providing a workpiece, the workpiece comprising a plurality of active areas;
analyzing the active areas to determine desired stress levels for each active area;
determining at least one first active area to have a first amount of stress and at least one second active area to have a second amount of stress;
forming a stress-controlling material over the at least one second active area but not over the at least one first active area; and
forming a stress-increasing material over the at least one first active area and over the stress-controlling material that is over the at least one second active area.

2. The method according to claim 1, wherein the second amount of stress is less than the first amount of stress, wherein the stress-controlling material reduces the amount that the stress-increasing material increases a stress level of the at least one second active area.

3. The method according to claim 1, wherein the at least one first active area is disposed in a first region, wherein the at least one second active area is disposed in a second region, further comprising a material layer disposed over the workpiece, the material layer comprising a third amount of stress, wherein the stress-increasing material increases the third amount of stress of the material layer in the first region by a greater amount than in the second region.

4. The method according to claim 1, wherein the first amount of stress and/or the second amount of stress comprise tensile or compressive stress.

5. The method according to claim 1, wherein disposing the stress-controlling material over the second region of the workpiece comprises:
forming the stress-controlling material over the at least one first active area and the at least one second active area; and
removing the stress-controlling material from over the at least one first active area.

6. A method of fabricating a semiconductor device, the method comprising:
providing a workpiece, the workpiece including a silicide region, a non-silicide region, and a stress-control region;
forming active areas in the silicide region, the non-silicide region, and the stress-control region;
disposing a first material over the active areas in at least the stress-control region, but not over the active areas in the silicide region; and
disposing a second material over the active areas in at least the silicide region and over the first material in at least the stress-control region, wherein the second material comprises a material that increases a stress in the active areas in at least the silicide region by a first amount, and wherein the first material comprises a material that increases a stress in the active areas in at least the stress-control region by a second amount, the second amount being different than the first amount.

7. The method according to claim 6, wherein forming the active areas in the silicide region, the non-silicide region, and the stress-control region comprises forming a plurality of transistors, the plurality of transistors including channel regions disposed within the workpiece, wherein disposing the second material over the active areas in at least the silicide region comprises increasing a stress of the channel region of the plurality of transistors in at least the silicide region by a first amount of stress, and wherein disposing the first material over the active areas in at least the stress-control region and disposing the second material over the first material in at least the stress-control region comprises increasing a stress of the channel region of the plurality of transistors in at least the stress-control region by a second amount of stress, the second amount of stress being less than the first amount of stress.

8. The method according to claim 6, further comprising forming a silicide over portions of the active areas of the silicide region, but not over the active areas in at least the non-silicide region.

9. The method according to claim 8, wherein disposing the first material over the active areas in at least the stress-control region further comprises disposing the first material over the active areas in the non-silicide region, wherein the first material prevents the formation of the silicide over active areas of the non-silicide region and the stress-control region.

10. The method according to claim 8, further comprising forming a third material over the active areas of at least the non-silicide region, before forming the silicide over portions of the active areas of the silicide region, wherein the third material prevents the formation of the silicide over active areas of at least the non-silicide region.

11. The method according to claim 10, wherein forming the third material over the active areas of at least the non-silicide region is performed before or after disposing the first material over the active areas in at least the stress-control region.

12. A method of fabricating a semiconductor device, the method comprising:
providing a workpiece;
disposing a gate dielectric material over the workpiece;
disposing a gate material over the gate dielectric material;
patterning the gate material and the gate dielectric material to form a gate and a gate dielectric of a first transistor and a second transistor;
forming at least one spacer over sidewalls of the gate and the gate dielectric of the first transistor and the second transistor;
forming a source region and a drain region proximate the at least one spacer of the first transistor and the second transistor, a channel region being disposed between the source region and the drain region of each of the first transistor and the second transistor;
forming a stress-controlling material over the source region, the drain region, the at least one spacer over sidewalls of the gate and gate dielectric, and a top surface of the gate of the second transistor; and
forming a stress-increasing material over the stress-controlling material over the second transistor and over the source region, the drain region, at least one spacer over sidewalls of the gate and gate dielectric, and a top surface of the gate of the first transistor, wherein a stress of the channel region of the first transistor is increased by the stress-increasing material by a greater amount than a stress of the channel region of the second transistor is increased.

13. The method according to claim 12, wherein disposing the stress-controlling material comprises forming about 40 nm or less of silicon nitride, SiON, or silicon dioxide.

14. The method according to claim 12, wherein disposing the stress-increasing material comprises forming about 75 nm or less of silicon nitride or SiON.

15. The method according to claim 12, further comprising forming a silicide on the source region, the drain region, and the gate of the first transistor, wherein the stress-controlling material prevents the formation of silicide on the source region, the drain region, and the gate of the second transistor.

16. The method according to claim 12, wherein fabricating the semiconductor device comprises fabricating a complementary metal oxide semiconductor (CMOS) device, wherein the first transistor comprises an n channel metal oxide semiconductor (NMOS) field effect transistor (FET) and wherein the second transistor comprises a p channel metal oxide semiconductor (PMOS) field effect transistor (FET), or wherein the first transistor comprises a PMOS FET and wherein the second transistor comprises an NMOS FET.

17. The method according to claim 16, wherein forming the stress-controlling material comprises increasing the operating current of the PMOS FET or the NMOS FET.

18. The method according to claim 12, wherein forming the stress-controlling material comprises forming a material layer having a predetermined amount of stress control on the stress-increasing material on the channel region of the second transistor, and wherein the predetermined amount of stress control is achieved by selecting a material thickness or deposition parameter values of pressure, deposition rate, deposition time, gas ratio, gas flow rate, or radio frequency (RF) power or frequency.

19. A semiconductor device, comprising:
a workpiece, the workpiece including a plurality of active areas disposed in a silicide region, a non-silicide region, and a stress-control region;
a stress-controlling material disposed over the active areas in at least the stress-control region, but not over the active areas in the silicide region;
a silicide formed over portions of the active areas in the silicide region, but not over portions of the active areas in at least the non-silicide region; and
a stress-increasing material disposed over the active areas in at least the silicide region and over the stress-controlling material in at least the stress-control region.

20. The semiconductor device according to claim 19, wherein the active areas in the silicide region have a greater amount of stress than the active areas in at least the stress-control region.

21. The semiconductor device according to claim 19, wherein the active areas in the silicide region, the non-silicide region, and the stress-control region comprise a plurality of transistors, the plurality of transistors including channel regions disposed within the workpiece, wherein the stress-increasing material disposed over the active areas in at least the silicide region increases a stress of the channel region of the plurality of transistors in the silicide region by a first amount of stress, and wherein the stress-controlling material over the active areas in at least the stress-control region and the stress-increasing material over the stress-controlling material in at least the stress-control region increases a stress of the channel region of the plurality of transistors in at least the stress-control region by a second amount of stress, the second amount of stress being less than the first amount of stress.

22. The semiconductor device according to claim 19, further comprising a protective material disposed over the active areas of at least the non-silicide region, the protective material being adapted to prevent the formation of the silicide over active areas of at least the non-silicide region.

23. The semiconductor device according to claim 22, wherein the protective material comprises about 40 nm or less of silicon nitride, SiON, or silicon dioxide.

24. The semiconductor device according to claim 19, wherein the stress-controlling material comprises a first stress-controlling material disposed over the active areas in a first portion of the stress-control region and a second stress-controlling material disposed over the active areas in a second portion of the stress-control region, wherein the first stress-controlling material reduces an effect of the stress-increasing material on the active areas by a first amount, and wherein the second stress-controlling material reduces an effect of the stress-increasing material on the active areas by a second amount, wherein the second amount is different than the first amount.

25. A semiconductor device, comprising:
a workpiece;
a first transistor and a second transistor formed over the workpiece, the first transistor and the second transistor each including a gate dielectric and a gate disposed over the gate dielectric, at least one sidewall spacer being disposed over sidewalls of the gate and the gate dielectric of the first transistor and the second transistor, the first transistor and the second transistor each including a source region and a drain region disposed within the workpiece proximate the at least one spacer, a channel region being disposed between the source region and the drain region of each of the first transistor and the second transistor;
a stress-controlling material disposed over the source region, the drain region, the at least one spacer over sidewalls of the gate and gate dielectric, and a top surface of the gate of the second transistor; and
a stress-increasing material disposed over stress-controlling material over the second transistor and over the source region, the drain region, the at least one spacer over sidewalls of the gate and gate dielectric, and a top surface of the gate of the first transistor.

26. The semiconductor device according to claim 25, wherein the channel region of the first transistor has a greater amount of stress than the channel region of the second transistor.

27. The semiconductor device according to claim 25, wherein the semiconductor device comprises a complementary metal oxide semiconductor (CMOS) device, wherein the first transistor comprises an n channel metal oxide semiconductor (NMOS) field effect transistor (FET) and the second transistor comprises a p channel metal oxide semiconductor (PMOS) field effect transistor (FET), or wherein the first transistor comprises a PMOS FET and the second transistor comprises an NMOS FET.

28. The semiconductor device according to claim 27, further comprising a silicide disposed on the source region, the drain region, and the gate of the NMOS FET or PMOS FET but not on the source region, the drain region, or the gate of the PMOS FET or NMOS FET.
